(19) United States
(12) Patent Application Publication
(10) Pub. No.: US 2026/0016278 A1
(43) Pub. Date: Jan. 15, 2026

(54) A SENSOR ASSEMBLY, A COMPONENT HANDLING ASSEMBLY, AND A METHOD OF DELIVERING A COMPONENT

(71) Applicant: Ismeca Semiconductor Holding SA, La Chaux-de-Fonds (CH)

(72) Inventors: Marco Oberli, La Chaux-de-Fonds (CH); Philippe Viverge, Le Russey (FR); Raphaël Eigeldinger, Colombier (CH); Eliot Carvalho Alves, La Chaux-de-Fonds (CH)

(21) Appl. No.: 18/995,760

(22) PCT Filed: Jun. 7, 2023
(86) PCT No.: PCT/IB2023/055858

§ 371 Date: Jan. 16, 2025

(30) Foreign Application Priority Data
Jul. 20, 2022 (CH) CH000866/2022

(51) Int. Cl. G01B 7/02; H05K 13/04; H05K 13/08

(52) U.S. Cl. CPC G01B 7/023; H05K 13/0404; H05K 13/081

(57) ABSTRACT

Disclosed is a sensor assembly. A sensor assembly can include an inductive sensor which can be arranged at a fixed position within the sensor assembly, a carrier assembly with an anchor member which can be arranged at a fixed position within the carrier assembly, and a moveable member which is moveable with respect to the anchor member. A moveable member can include a foot portion suitable for cooperating with a pick-up head assembly and a metallic head portion which can interact with a magnetic field generated by the inductive sensor. A sensor assembly can include a spring member which is arranged so that when the foot portion is moved towards the anchor member the spring is compressed between the anchor member and the foot portion.

### FIELD OF THE INVENTION

The present invention concerns a sensor assembly which comprises an inductive sensor and a carrier assembly wherein the inductive sensor is operable to provide an output to a controller, said output being indicative of the magnitude a spring member in the carrier assembly is compressed. There is further provided a component handling assembly which uses the sensor assembly; and a method of delivering a component to a receiving surface which uses the component handling assembly.

### BACKGROUND TO THE INVENTION

Many component handling assemblies include a delivery station where a component which are held on a pickup head of a pickup member, are delivered to a receiving surface (e.g. the components are delivered onto the surface of a shuttle which is destined to transport the components to another station). The pickup member is usually located at a periphery of a rotatable turret and the pickup member extends away from the turret to move the pickup head to a position which is above the receiving surface. The position of the pickup head, which holds the component, relative to the receiving surface is critical to ensure satisfactory delivery of the component to the receiving surface: if the pickup head is too far away from the receiving surface then the component will need to fall a larger distance and become displaced from a predefined desired position when it impacts the receiving surface; in other words, when the pickup head is too far away from the receiving surface then it is not possible to deliver the component accurately to a predefined desired position on the receiving surface. On the other hand, if the pickup head is moved too close to the receiving surface, then the component will be compressed between the pickup head and the receiving surface and become damaged.

In component handling assemblies a driver member of an actuator, pushes the pickup member to extend it away from the turret so that the pickup head is moved to a position where it delivers the component it holds to the receiving surface; accordingly, the position of the pickup head is directly related to the position of the driver member.

Existing solutions for ensuring optimum distance between the pickup head, involve first determining in a calibration step, a set point position for the driver member: the calibration involves positioning the receiving surface (e.g. the shuttle) beneath the pickup head a predefined target position, and then moving the drive member to push the pickup to bring the pickup head to a predefined height above the receiving surface; once the pickup head is at the predefined height above the receiving surface, the position of the driver member is determined using a sensor/tracking sensor (such as an optical encoder) and said measured position defines the set point position. Then, for all subsequent operations of delivering a component to a receiving surface, the receiving surface (e.g. the shuttle) is located at a position corresponding to the predefined target position, and the driver member is moved to a position corresponding to the set point position (the position being determined using a sensor (such as an optical encoder)), and the component is then delivered to the receiving surface.

Existing solutions for ensuring optimum distance between the pickup head, which holds the component, and the receiving surface, are inadequate at least because they cannot account for changes or variations which occur within the component handling assembly (such as changes or variations which occur within the component handling assembly while operating and/or after operating). For example parts of the component handling assembly will undergo thermal expansion during use, and the changes the dimensions of these parts which in turn will lead to variations in the distance between the pickup head, which holds the component, and the receiving surface; parts of the component handling assembly will undergo wear and tear over time, which will lead to changes in the relative positioning of parts within the component handling assembly and/or allow for a larger play in the positions of the parts within the component handling assembly, which in turn will lead to variations in the distance between the pickup head, which holds the component, and the receiving surface. Furthermore, the variations in the receiving surface will also lead to variations in the distance between the pickup head, which holds the component, and the receiving surface; for example, the receiving surface is usually a surface of a shuttle and the orientation of the shuttle may be tilted so that some parts of the receiving surface will be closer to the pickup head than other parts of the receiving surface. In order to achieve a precise distance between the pickup head, which holds the component, and the receiving surface of the shuttle, the orientation of the shuttle must be precise; in practice it is difficult and costly to achieve consistent precis orientation (e.g. consistent precis planarity) of the shuttle for multiple iterations over time.

It is an aim of the present invention to mitigate or obviate at least some of the above-mentioned problems/disadvantages associated with existing solutions.

### SUMMARY OF THE INVENTION

According to the present invention, this aim is achieved by, a sensor assembly having the features recited in independent claim 1; and/or by a component handling assembly having the features recited in independent claim 6; and/or by a method having the steps recited in independent claim 13. The dependent claims recite favourable, optional, features of various embodiments of the inventions.

### BRIEF DESCRIPTION OF THE DRAWINGS

Embodiments of the invention, which are given by way of example only, will be described in the detailed description, with reference to the following drawings in which:

FIG. 1a is a perspective view of a sensor assembly according to an embodiment of the present invention;

FIG. 1b is a side view of the sensor assembly of FIG. 1a;

FIG. 1c is a cross-sectional view of the sensor assembly of FIGS. 1a and 1b;

FIG. 2 is a perspective view of a component handling assembly according to an embodiment of the present invention;

FIG. 3 is a side view of the component handling assembly of FIG. 2.

### DETAILED DESCRIPTION OF EMBODIMENTS OF THE INVENTION

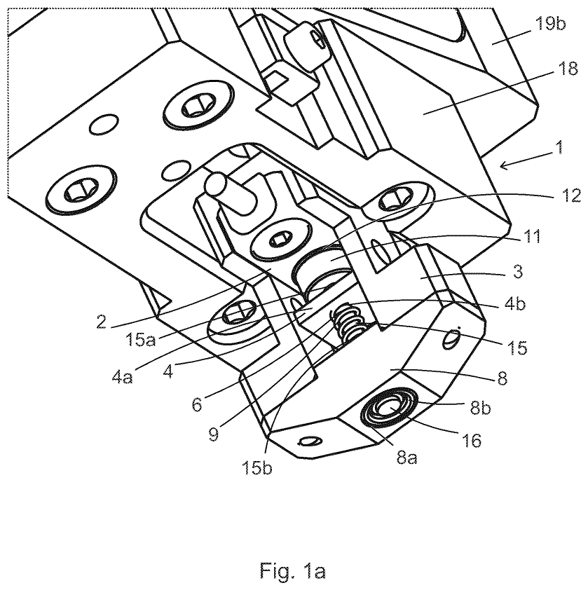

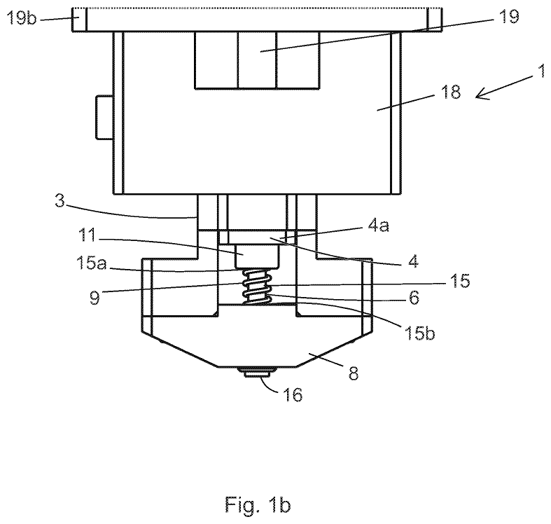

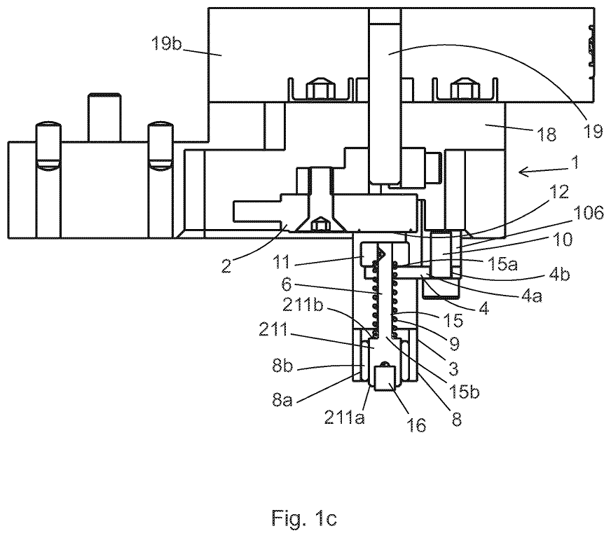

FIG. 1a is a perspective view of a sensor assembly 1 according to an embodiment of the present invention; FIG. 1b is a side view of the sensor assembly 1; and FIG. 1c is a cross sectional view of the sensor assembly 1.

Referring to FIGS. 1a, 1b, and 1c, it can be seen that the sensor assembly 1 comprises a carrier assembly 3. The carrier assembly 3 is selectively movable by a moveable drive member 19 of a drive assembly 19b.

The sensor assembly 1 further comprises an inductive sensor 2 which comprises a sensor pad 12. The inductive sensor 2 is fixed to the carrier assembly 3. It should be noted that in one embodiment the position of the inductive sensor 2 on the carrier assembly 3 may be adjustable; for example, the inductive sensor 2 may be mounted on the carrier assembly 3 by a mounting module which has a position adjustment means which allows the inductive sensor 2 to be moved to a higher fixed position or moved to a lower fixed position within the sensor assembly 1. However, adjustment of the fixed position of the inductive sensor 2 is not an essential feature of the present invention.

The carrier assembly 3 comprises an head member 8 having a channel 8a defined therein. In this example the head member 8 further comprises a guide member 8b which is located in the channel 8a; although it should be understood that the guide member 8b is not essential to the invention.

The carrier assembly 3 further comprises an anchor member 4 which can be arranged at a fixed position within the carrier assembly 3. In a preferred embodiment the position of the anchor member 4 in the carrier assembly 3 may be adjustable.

In this embodiment the anchor member 4 comprises a plate 4a which is arranged at a fixed position within the carrier assembly 3. The plate 4a has a through-hole 4b defined therein. The plate 4a is preferably mounted, via one or more screw members, on the carrier assembly 3 (preferably on a fixed part of the carrier assembly 3); the fixed position of the plate 4a can be selectively adjusted by screwing or unscrewing the one or more screw members. As shown in FIG. 1c the plate 4a is mounted, via a screw member 104, on a fixed part 106 of the carrier assembly 3; the fixed position of the plate 4a can be selectively adjusted by screwing or unscrewing the screw member 104 so as to move the plate 4a to a higher or lower position respectively (

The sensor assembly 1 further comprises a moveable member 6. The moveable member 6 comprises a foot portion 211, a metallic head portion 11, and a shaft member 15 which is connected between the foot portion 211 and metallic head 11. The shaft member 15 is fixedly connected at one end 15a thereof to the metallic head portion 11 and is fixedly connected at the other end 15b thereof to the foot portion 211.

The shaft member 15 is arranged to extend through the through-hole 4b defined in the anchor member 4 so that the metallic head portion 11 is located on one side of the anchor member 4 and the foot portion 211 is located on the other, opposite, side of the anchor member 4.

The metallic head portion 11 is located between the anchor member 4 and the inductive sensor 2. The metallic head portion 11 can interact with a magnetic field generated by the inductive sensor 2. In this embodiment the inductive sensor 2 and moveable member 6 are arranged so that the sensor pad 12 is aligned with the metallic head portion 11.

The foot portion 211 is located within the channel 8a of the head member 8; more specifically the foot portion 211 is located within the guide member 8b which is located in the channel 8a of the head member 4. A free end 211a of the foot member 211 projects from the guide member 8b. The foot portion 211 further comprises a tip member 16 which can abut a pick-up head assembly. The tip member 16 projects from the free end of the foot portion 211. In this embodiment the tip member 16 is partially embedded in the foot portion 211; however, it should be understood that the tip member 16 could alternatively be mounted on a surface of the free end of the foot portion 211. In this embodiment the tip member 16 is composed of a rubber material; however, it should be understood that the tip member 16 may have any suitable composition.

The moveable member 6 is moveable with respect to the carrier assembly 3 and the inductive sensor 2: the foot end portion 211 can move linearly through the guide member 8b (and/or the foot end portion 211 can move linearly through the channel 8a) and the shaft member 15 can move, linearly, through the through-hole 4b of the anchor member 4.

The sensor assembly 1 further comprises a spring 9 which is arranged between the anchor member 4 and the foot member 211. In the embodiment a first end 9a of the spring 9 abuts, or is attached to, the foot member 211, and a second, opposite end 9b, of the spring 9 abuts, or is attached to, the anchor member 4. As can be seen in FIG. 1c the first end 9a of the spring 9 abuts, or is attached to a second end 211b of the foot member 211 which is opposite to the free end 211a; this second end 211b of the foot member 211 is attached to the shaft 15; the second, opposite end 9b, of the spring 9 abuts, or is attached to, the surface of the anchor member 4 which is facing towards the foot member 211.

It is possible to selectively adjust the fixed position of the anchor member 4 by screwing or unscrewing the screw member 104 so as to move the anchor member 4 to a higher or lower position respectively so to account for different spring lengths/forces.

The inductive sensor 2 is operable to provide an output, wherein the value of said output depends on the distance between the metallic head portion 11 and the sensor pad 12 of the inductive sensor 2, so that the value of the output is representative of the magnitude the spring member 9 is compressed between the anchor member 4 and the foot portion 211. The magnitude which the spring member is compressed 9 is thus representative of the force which is applied to the tip member 16. In this embodiment the value of said output increases the more the spring member 9 is compressed; in other words when the spring member 9 is fully compressed the value of the value of output of the inductive sensor 2 will be a maximum value; and when the spring member 9 is fully uncompressed the value of the value of the output of the inductive sensor 2 will be a minimum value.

When a force, which is greater than the biasing force applied by the spring 9 to the foot member 211, is applied to the tip member 16 the moveable member 6 is moved so that the foot portion 211 is moved in a direction towards the anchor member 4 (The foot member 211 will move, through the guide member 8b (and/or channel 8a), towards the anchor member 4. In an embodiment the free end 211a of the foot member 211 can be moved into the guide member 8b (and/or channel 8a) leaving only a portion of the tip member 16 projecting from the guide member 8b (and/or channel 8a)); the shaft member 15 will move through the through-hole 4b as the foot portion 211 moves towards the anchor member 4; and the spring member 9 will be compressed between the anchor member 4 and the foot portion. Since the shaft member 15 is fixedly connected at one end 15a thereof to the metallic head portion 11 and is fixedly connected at the other end 15b thereof to the foot portion 211, when the foot portion 211 moves in a direction towards the anchor member 4, the metallic head portion 11 will also correspondingly move in a direction towards the sensor pad 12 of the inductive sensor 2 thereby decreasing the distance between a sensor pad 12 and the metallic head portion 11, and resulting in an increase in the value of the output of the inductive sensor 2.

Likewise when the moveable member 6 moves so that the foot portion 211 is moved in a direction away from the anchor member 4 (e.g. the moveable member 6 may be moved so that the foot portion 211 is moved in a direction away from the anchor member 4 (the foot member 211 will move, through the guide member 8b (and/or channel 8a), in a direction away from the anchor member 4) by a force which is applied to the foot portion 211 by the spring member 9 when the spring member 9 is in a compressed state (i.e. when the spring member 9 is compressed between the foot portion 211 and anchor member 4, the spring member 9 will recoil towards an uncompressed state thereby applying force to the foot portion 211 which moves the foot portion 4 in a direction away from the anchor member 4); since the shaft member 15 is fixedly connected at one end 15a thereof to the metallic head portion 11 and is fixedly connected at the other end 15b thereof to the foot portion 211, when the foot portion 211 moves in a direction away from the anchor member 4 the metallic head portion 11 will also correspondingly move in a direction away from the sensor pad 12 thereby increasing the distance between a sensor pad 12 and the metallic head portion 11, and resulting in a decrease in the value of the output of the inductive sensor 2.

The sensor assembly 1 further comprises a mounting module 18 configured to allow the sensor assembly 1 to be mounted on a drive assembly 19b which comprises a moveable drive member 19. The carrier assembly 3 is moveable with respect to the mounting module 18. The drive member 19 of the drive assembly 19b can cooperate with the carrier assembly 3 to selectively move the carrier assembly 3. The mounting module 18 can be fixed to the drive assembly 19b so that the mounting module 18 and the drive assembly have a fixed position; the drive member 19 is selectively operated to move to apply a force to the carrier assembly 3 to force the carrier assembly 3 to move in a direction towards a pickup member.

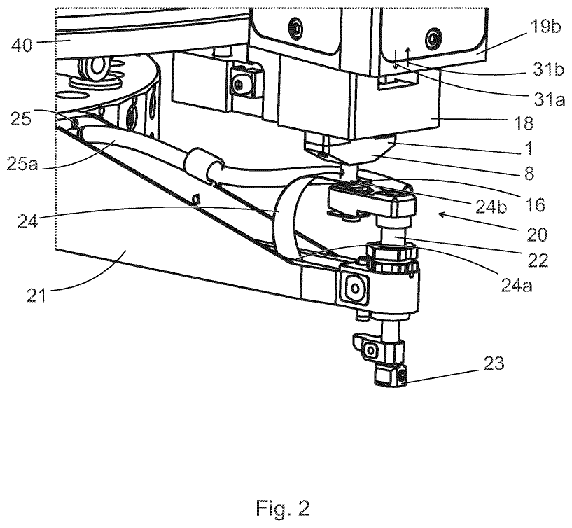

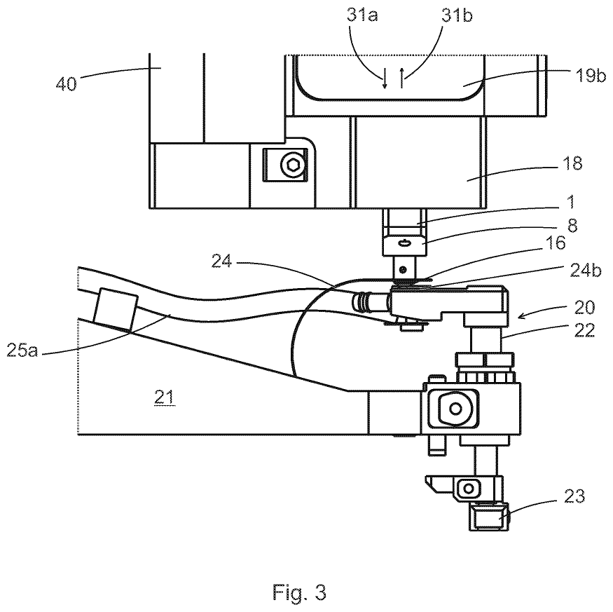

FIG. 2 is a perspective view of a component handling assembly 20 according to an embodiment of the present invention; FIG. 3 is a side view of the handling assembly 20. Referring to FIGS. 2 and 3 it can be seen that the component handling assembly 20 comprises a turret arm member 21 having a pickup member 22. The pickup member 22 comprises has a pickup head 23. The pickup member 22 is moveable relative to the turret arm member 21, between a first position wherein the pickup head 23 of the pickup member 22 is at a minimum distance from the turret arm member 21, and a second position wherein the pickup head 23 of the pickup member 22 is at a maximum distance from the turret arm member 21.

The component handling assembly 20 further comprises a biasing means 24 which biases the pickup member 22 towards its first position. In this embodiment the biasing means 24 comprises a blade 24 which is fixed at a first end 24a thereof to the turret arm member 21 and is fixed at a second, opposite, end 24b thereof to a top portion 22a of the pickup member 22. When the pickup member 22 is moved towards its first position, the second end 24b of the blade 24 moves together with the pickup member 22, while the first end 24a of the blade remains in a fixed position; thus when the pickup member 22 is moved towards its first position blade 24 is flexed; when the blade 24 is in its flexed state it applies a pulling force to the top portion 22a of the pickup member 22 which biases the pickup member 22 towards its first position. It should be understood that in the present invention the biasing means 24 may take any suitable form, and it not limited to being a blade 24.

The component handling assembly further comprises an air flow generating means 25 which is selectively operable to generate a negative air flow or a positive air flow. The air flow generating means 25 is fluidly connected to the pickup member 22 so that, a vacuum can be selectively provided at the pickup head 23 so that a component can be held, by said vacuum, on the pickup head 23, when the air flow generating means is operated to generate a negative air flow; and so that a component held on the pickup head can be blown from the pickup head 23 onto a receiving surface, when the air flow generating means 25 is operated to generate a positive air flow. In this embodiment the air flow generating means 25 is fluidly connected to the pickup member 22 via a conduit 25a.

The component handling assembly 20 further comprise an drive assembly 19b and a sensor assembly 1 according to any of the aforementioned sensor assembly 1 embodiments.

The drive assembly 19b comprises at least one motor and a drive member 19 (not visible in FIG. 2 or 3, but visible in FIGS. 1b, 1c) operably attached to the motor so that the motor is operable to move the drive member 19 in a first direction (indicated by arrow 31a), or in a second, opposite, direction (indicated by arrow 31b). The first direction 31a is a direction which is toward the pickup member 22; while the second direction 31b is a direction which is away from the pickup member 22.

The sensor assembly 1 is attached, via the mounting module 18, to the drive assembly 19b. The carrier assembly 3 of the sensor assembly 1 is moveable with respect to the mounting module 18. The drive member 19 of the drive assembly 19b can cooperate with the carrier assembly 3 to selectively move the carrier assembly 3 in a direction towards a pickup member 22. The sensor assembly 1 is arranged so that the drive member 19 (not visible in FIG. 2 or 3, but visible in FIGS. 1b, 1c) of the drive assembly 19b is selectively operable to apply a force to the carrier assembly 3 of the sensor assembly 1 to move the carrier assembly 3 in the first direction 31a towards the pickup member 22. (The inductive sensor 2, anchor member 4 and moveably member 6 will all move together with the carrier member 3 towards the pickup member 22)

The sensor assembly 1 is arranged so that the foot portion 211 (more specifically, the tip member 16 of the foot portion 211) is aligned above, or abuts, the top portion 24a of pickup member 22; so that when the motor of the drive assembly 19b is operated to move the drive member 19 in the first direction 31a, the drive member 19 of the drive assembly 19b will apply a force to the carrier assembly 3 of the sensor assembly 1 to move the carrier assembly 3 in the first direction 31a towards the pickup member 22, so that the tip member 16 of the foot portion 211 of the sensor assembly 1 will apply a force to the pickup member 22 (said applied force being greater than and against the biasing force applied by the biasing means 24 to the pickup member 22) to move the pickup member 22 from its first position towards its second position.

The spring member 9 in the sensor assembly 1 has a spring stiffness which is high enough to resist a force equivalent to the biasing force applied by the biasing means 24 to the pickup member 22 when the pickup member 22 is in its second position, so that compression of the spring member 9 occurs only in reaction to a counter force is applied to the pickup head 22. More specifically, in this embodiment, the spring member 9 has a spring stiffness which is high enough to resist a force equivalent to the pulling force which the blade 24 applies to the top portion 22a of the pickup member 22 when the pickup member 22 is in its second position.

The component handling assembly 20 further comprises a controller 40 which is operably connected to the inductive sensor 2 of the sensor assembly 1 so that the controller 40 can receive the output from the inductive sensor 2, and is also operably connected to the drive assembly 19b so that the controller 40 can control the motor of the drive assembly 19b. The controller 40 is configured to operate motor of the drive assembly 19b to move the drive member 19 in a first direction 31a, until the output of the inductive sensor 2 increases to be within a predefined range. In an preferred embodiment the predefined range is between a non-zero value and a predetermined maximum value, wherein the predetermined maximum value is equal to an output of the inductive sensor 2 when the spring member 9 is compressed by 50 μm. In another embodiment the predefined range is between a predefined minimum value and a predetermined maximum value, wherein the predefined minimum is equal to an output of the inductive sensor 2 when the spring member 9 is compressed by 10 μm and the predetermined maximum value is equal to output of the inductive sensor 2 when the spring member 9 is compressed by 50 μm.

The controller 40 is also operably connected to the air flow generating means 25; the controller is configured to selectively operate the air flow generating means 25 to generate a negative air flow and/or a positive air flow.

The component handling assembly 20, according to any of the aforementioned component handling assembly embodiments, can be used to perform a method of delivering a component which is held on a pickup head to a receiving surface, according to a further aspect of the present invention, the method comprising the steps of, moving a pickup head which holds a component, towards a receiving surface so that the component is pressed against the receiving surface, and the receiving surface provides a reaction force against the component which forces the foot portion 211 the moveable member 6 to move towards the anchor member 4 thereby compressing the spring member 9 between the anchor member 4 and the foot portion 211; continuing to move the pickup head which holds a component, towards the receiving surface, until the output of the inductive sensor 2 increases to be within a predefined range. This allows the component held on the pickup head 23 to be placed with the desired level of force onto the receiving surface even if variations in the distance between the respective pickup heads 23 and receiving surfaces (e.g. the surfaces of respective shuttles which receive components from respective pickup heads 23) occurs during operation of the component handling assembly 20.

In a preferred embodiment of the method, if, after the drive member 19 has moved in the first direction 31a a distance which is equal to the predefined threshold distance, the output of the inductive sensor 2 is not within a predefined range (i.e. the output of the inductive senor 2 has not increased a sufficient amount to be within said predefined range), the method further comprises the steps moving the drive member 19 (e.g. operating the motor of the drive assembly 19b to move the drive member 19), iteratively, in predefined increments, in the first direction 31a, so that the tip member 16 of the foot portion 211 is moved in corresponding predefined increments in the first direction 31a, towards the pickup member 22 to cause the pickup head 23 to move in corresponding predefined increments towards the receiving surface, until the output of the inductive sensor 2 increases to be within the predefined range. Thus, the preferred embodiment may comprise the steps of detecting the drive member has moved a distance which is equal to the predefined threshold distance, and that the output of the inductive sensor is not within a predefined range; in response to said detection, moving the drive member, iteratively, in predefined increments, so that the pickup head 23 is moved in corresponding predefined increments towards the receiving surface, until the output of the inductive sensor increases to be within the predefined range. In an embodiment the predefined increments are in the range 0.001 mm-0.05 mm.

During operation of the component handling assembly 20: The pickup member 22 will initially be in its first position; so, initially the spring member 9 will be in an uncompressed state. The controller 40 will have operated the air flow generating means 25 so that the air flow generating means 25 generates a negative air flow so as to create a vacuum at the pickup head 23; this vacuum will hold a component, which is to be delivered to a receiving surface, on the pickup head 23. In this example the receiving surface will be a surface of a moveable shuttle; however it should be understood that the present invention is not limited to the receiving surface being defined by a surface of a shuttle. The component in question may have been picked by the pickup member 22 from a processing station or test station.

A shuttle, having a surface which can receive one or more components, will be positioned below the pickup head 23. The shuttle may be located on track and may drive to a position where its surface is aligned below the pickup head 23.

While the component is held by vacuum on the pickup head 23, the controller 40 operates motor of the drive assembly 19b to move the drive member 19 in a first direction 31a. The first direction 31a is a direction which is toward the pickup member 22.

The drive member 19 of the drive assembly 19b will apply a force to the carrier assembly 3 of the sensor assembly 1 to move the carrier assembly 3 in the first direction 31a towards the pickup member 22 to bring the tip member 16 of the foot portion 211 into contact with the pickup member 22. As the drive member 19 of the drive assembly 19b continues to apply a force to the carrier assembly 3 of the sensor assembly 1 to move the carrier assembly 3 in the first direction 31a towards the pickup member 22, the force applied by the drive member to the carrier assembly 3 will be transmitted through the carrier assembly 3 to the tip member 16 of the foot portion 211, so that the tip member 16 of the foot portion 211 applies a force to the pickup member 22 to move the pickup member from its first position towards its second position.

Since the spring member 9 in the sensor assembly 1 has a spring stiffness which is high enough to resist a force equivalent to the biasing force applied by the biasing means 24 to the pickup member 22 when the pickup member 22 is in its second position, the movement of the pickup member 22 from its first position towards its second position will not cause any compression of the spring member 9 in the sensor assembly 1. More specifically, since the spring member 9 has a spring stiffness which is high enough to resist a force equivalent to the pulling force which the blade 24 applies to the top portion 22a of the pickup member 22 when the pickup member 22 is in its second position, the movement of the pickup member 22 from its first position towards its second position will not cause any compression of the spring member 9 in the sensor assembly 1.

However as soon as the component, which is held on pickup head 23, abuts the surface of the shuttle the surface of the shuttle will block the pickup head 23 moving any further in the first direction 31a; this will result in a reaction force, applied by the surface of the shuttle against the component which is being pressed by the pickup head 23 onto the shuttle surface. This reaction force is transmitted through the component, though the pickup head 23, through the pickup member 22, to the tip member 16 of the foot portion 211 of the moveable member 6.

The reaction force will force the foot portion 211 of the moveable member 6 to move towards the anchor member 4, thereby causing compression of the spring member 9 between the anchor member 4 and the foot portion 211. The more the drive member 19 moves in a first direction 31a the greater the reaction force which is transmitted to the tip member 16 of the foot portion 211 of the moveable member 6, and thus the more the spring member 9 will be compressed between the anchor member 4 and the foot portion 211.

The controller 40, which is operably connected to the inductive sensor 2 of the sensor assembly 1 will receive the output from the inductive sensor 2. The controller 40 operates the motor of the drive assembly 19b, to continue to move the drive member 19 in the first direction 31a, until the output from the inductive sensor 2 increases to be within a predefined range. In this embodiment the predefined range is between a predefined maximum value and a predetermined minimum value, wherein the predefined maximum value is equal to output of the inductive sensor 2 when the spring member 9 is compressed by 50 μm and the predetermined minimum value is equal to output of the inductive sensor 2 when the spring member 9 is compressed by 10 μm. (The less spring member 9 is compressed the higher the distance between the metallic head portion 11 and the sensor pad 12 and therefore the smaller the value of the output of the inductive sensor 2; the more the spring member 9 is compressed the lower the distance between the metallic head portion 11 and the sensor pad 12 and therefore the higher the value of the output of the inductive sensor 2; therefore the predefined maximum value occurs when the spring member is compressed by 50 μm and the predetermined minimum value occurs when the spring member 9 is compressed by 10 μm)

It should be understood that the predetermined maximum value and predetermined minimum value are determined in a calibration step, which is preferably carried out prior to use of the component handling assembly 20; the calibration step preferably involves compressing the spring member by 10 μm and reading and recording the value output from the inductive sensor 2 to obtain the predetermined minimum value; and compressing the spring member by 50 μm and reading and recording the output from the inductive sensor 2 to obtain the predetermined maximum value. In this way component handling assembly 20 can always be operated so that the pickup head 23 applies a desired level of force to the component when delivering the component to the receiving surface, even if variations in the distance between the pickup head 23 and the receiving surface occur over time.

Once the output from the inductive sensor 2 increases to be within a predefined range the controller 40 stops the motor of the drive assembly 19b from further moving the drive member 19 in the first direction 31a. At this point the component is released from the pickup head 23: in order to do this the controller 40 operates the air flow generating means to stop the air flow generating means from generating a negative air flow, so as to remove the vacuum which was used to hold the component on the pickup head 23. Once the vacuum is removed the component will be released from the pickup head 23 and the component will have been delivered to the surface of the shuttle.

In the preferred embodiment, once the output from the inductive sensor 2 increases to be within a predefined range, the controller 40 will operate the air flow generating means to generate a positive air flow; this positive air flow blows the component away from the pickup head 23 thereby assisting removal of the component from the pickup head 23 (and thus assisting the delivery of the component onto the surface of the shuttle). When the pickup head 23 applies a pressing force to the component this may result in the component becoming loosely attached, by friction, to the pickup head 23; the positive air flow will overcome any frictional attachment between the pickup head 23 and component so that the position of the component on the surface of the shuttle does not become displaced when the pickup head is moved away from the component. However, it should be understood that the application of a positive air flow to assist removal of the component from the pickup head 23 is not essential to the present invention.

The controller 40 then operates motor of the drive assembly 19b to move the drive member 19 in its second, opposite, direction 31b. Accordingly the force that the drive member 19 was applying to the carrier assembly 3 of the sensor assembly 1 to move the carrier assembly 3 in the first direction 31a towards the pickup member 22, is removed, thereby removing the force which was applied, via the tip member 16 of the foot portion 211, to the pickup member 22. As the force which was applied, via the tip member 16 of the foot portion 211, to the pickup member 22, is removed, the biasing force applied by the biasing means 24 to the pickup member will move the pickup member 22 back to its first position; specifically the pulling force which the blade 24 applies to the top portion 22a of the pickup member 22 will move the pickup member 22 back to its first position. In one embodiment as the pickup member 22 is moved by the pulling force of the blade 24 the pickup member 22 pushes on the tip member 16 of the foot portion 211 which cause the carrier 3 to move upwards in a direction away from the receiving surface.

In a preferred embodiment the component handling assembly 20 the drive assembly 19b further comprises a distance sensor which is configured to measure the distance the drive member 19 has moved, in the first direction 31a, from a predefined reference position, and to output a distance measurement which is indicative of said measured distance. In this further embodiment the controller 40 is operably connected to said distance sensor so that the controller 40 receives the distance measurement from the distance sensor; the controller 40 is configured to compare the received distance measurement with a predefined threshold distance, and if the received distance measurement is equal to, or greater than, the predefined threshold distance the controller 40 operates motor of the drive assembly 19b to move the drive member 19, iteratively, in predefined increments, in the first direction 31a, until the output from the inductive sensor 2 increases to be within the predefined range. The predefined threshold distance is determined in a calibration step, and is the distance which drive member 19 has moved, in the first direction 31a, from a predefined reference position, when the pickup head 23 is a predefined distance away from a receiving surface (e.g. the surface of a shuttle which is positioned below the pickup head 23) which has been located at a predefined position below the pickup head 23 (the predefined position preferably corresponds to the position a surface of a shuttle will be from the pickup head 23 when the component handling assembly 20 is in use); preferably the predefined threshold distance is the distance which drive member 19 has moved, in the first direction 31a, from the predefined reference position, when the pickup head 23 occupies a predefined position (or is within a predefined position range) where the component is to be released from the pickup head 23 onto the receiving surface. In an embodiment, during operation of the component handling assembly 20, after a shuttle with a receiving surface has be positioned below the pickup head 23, when the drive member 19 has moved in the first direction 31a a distance which is equal to the predefined threshold distance, but the output from the inductive sensor 2 is not within said predefined range, this means that the receiving surface (i.e. the surface of the shuttle) is further away from the pickup head 23 than the distance the receiving surface was away from the pickup head 23 during the calibration step (the reason for the receiving surface being further away from the pickup head may be due to thermal expansion of parts of the assembly, and/or due to wear and tear of parts of the assembly, for example). The controller 40 then operates the motor of the drive assembly 19b to move the drive member 19, iteratively, in predefined increments, in a first direction 31a, until the output from the inductive sensor 2 increases to be within the predefined range. Therefore, even though a variation in the distance between the pickup head 23 and the receiving surface occurred, the component will be placed with the desired level of force onto the receiving surface.

Various modifications and variations to the described embodiments of the invention will be apparent to those skilled in the art without departing from the scope of the invention as defined in the appended claims. Although the invention has been described in connection with specific preferred embodiments, it should be understood that the invention as claimed should not be unduly limited to such specific embodiment.

1. A sensor assembly comprising,
an inductive sensor configured to be arranged at a first fixed position within the sensor assembly;
a carrier assembly, comprising an anchor member configured to be arranged at a second fixed position within the carrier assembly;
a moveable member which is moveable with respect to the anchor member, wherein the moveable member comprises a foot portion suitable for cooperating with a pick-up head assembly, and a metallic head portion configured to interact with a magnetic field generated by the inductive sensor; and
a spring member which is arranged so that when the foot portion is moved towards the anchor member the spring member is compressed between the anchor member and the foot portion;
wherein the inductive sensor is operable to provide an output, wherein a value of said output depends on a distance between the inductive sensor and the metallic head portion, so that the output is representative of a magnitude the spring member is compressed between the anchor member and the foot portion.

2. The sensor assembly according to claim 1, wherein the anchor member comprises a plate configured to be arranged at the second fixed position within the carrier assembly, and wherein the anchor member has a through-hole defined therein; and
wherein the moveable member comprises a shaft member which is connected between the metallic head portion and the foot portion; and wherein the shaft member is arranged to extend through the through-hole in the anchor member so that the metallic head portion is located on one side of the anchor member and the foot portion located on an other, opposite side of the anchor member.

3. The sensor assembly according to claim 1, wherein the foot portion comprises a tip member configured to abut the pick-up head assembly.

4. The sensor assembly according to claim 1, wherein the inductive sensor comprises a sensor pad; and wherein the inductive sensor is arranged so that the sensor pad is aligned with the metallic head portion so that when the foot portion is moved towards the anchor member and the spring member is compressed between the anchor member and the foot portion, the metallic head portion moves towards the sensor pad.

5. The sensor assembly according to claim 1, wherein the anchor member is mounted, via one or more screws, on a fixed part of the carrier assembly, and wherein the second fixed position of the anchor member can be selectively adjusted by screwing or unscrewing the one or more screws serew members.

6. A component handling assembly comprising,
a turret arm member having a pickup member having a pickup head, wherein the pickup member is moveable relative to the turret arm member, between a first position wherein the pickup head of the pickup member is at a minimum distance from the turret arm member, and a second position wherein the pickup head of the pickup member is at a maximum distance from the turret arm member, and a biasing means which biases the pickup member towards its first position;
a drive assembly which comprises at least one motor and a drive member operably attached to the motor so that the motor is operable to move the drive member in a first direction, or in a second, opposite direction;
the sensor assembly according to claim 1, wherein the sensor assembly is arranged so that the foot portion cooperates with the pickup member, so that when the motor of the drive assembly is operated to move the drive member in the first direction the foot portion will apply
a force to the pickup member to move the pickup member from the first position towards the second position.

7. The component handling assembly according to claim 6, wherein the spring member has a spring stiffness high enough to resist a force equivalent to a biasing force applied by the biasing means to the pickup member when the pickup member is in the second position, so that compression of the spring member occurs only in reaction to a counter force is applied to the pickup head.

8. The component handling assembly according to claim 6, further comprising a controller which is operably connected to the inductive sensor of the sensor assembly so that the controller can receive the output from the inductive sensor, and is also operably connected to the drive assembly so that the controller can control the motor of the drive assembly; and
wherein the controller is configured to operate the motor to move the drive member in the first direction, until the output of the inductive sensor increases to be within a predefined range.

9. The component handling assembly according to claim 8, wherein the predefined range is any non-zero value which is less than a predetermined maximum value, wherein the predetermined maximum value is equal to the output of the inductive sensor when the spring member is compressed by 50 μm.

10. The component handling assembly according to claim 8, wherein the predefined range is between a predefined minimum value and a predetermined maximum value, wherein the predefined minimum value is equal to the output of the inductive sensor when the spring member is compressed by 10 μm and the predetermined maximum value is equal to the output of the inductive sensor when the spring member is compressed by 50 μm.

11. The component handling assembly according to claim 8, wherein the drive assembly further comprises a distance sensor which is configured to measure the distance the drive member has moved from a predefined reference position, and to output a distance measurement which is indicative of the distance the drive member has moved from the predefined reference position; and
wherein the controller is operably connected to said distance sensor so that the controller receives the distance measurement, and compare the received distance measurement with a reference distance measurement, and upon the distance measurement exceeding a predefined threshold, the controller is configured to operate the motor of the drive assembly to move the drive member, iteratively, in predefined increments, in the first direction, until the output of the inductive sensor increases to be within the predefined range.

12. The component handling assembly according to claim 6, further comprising an air flow generating means which is selectively operable to generate a negative air flow and/or a positive air flow;
wherein the air flow generating means is fluidly connected to the pickup member so that, a vacuum can be selectively provided at the pickup head so that a component can be held, by said vacuum, on the pickup head, when the air flow generating means is operated to generate the negative air flow; and the component held on the pickup head can be blown from the pickup head onto a receiving surface, when the air flow generating means is operated to generate the positive air flow.

13. A method of using the component handling assembly according to claim 6 to deliver a component held on the pickup member to a receiving surface, the method comprising:
moving the pickup member which holds the component, towards the receiving surface so that the component is pressed against the receiving surface and the receiving surface provides a reaction force against the component which forces the foot portion of the moveable member to move towards the anchor member thereby compressing the spring member between the anchor member and the foot portion;
continuing to move the pickup member which holds the component, towards the receiving surface, until the output of the inductive sensor increases to be within a predefined range.

14. The method according to claim 13 further comprising:
detecting the drive member has moved a distance which is equal to a predefined threshold distance, but the output of the inductive sensor is not within the predefined range; and
in response to said detection, moving the drive member, iteratively, in predefined increments, so that the pickup head is moved in corresponding predefined increments towards the receiving surface, until the output of the inductive sensor increases to be within the predefined range.
